(19) United States
(12) Patent Application Publication
(10) Pub. No.: US 2019/0311983 A1
(43) Pub. Date: Oct. 10, 2019

(54) STACKING MULTIPLE DIES HAVING DISSIMILAR INTERCONNECT STRUCTURE LAYOUT AND PITCH

(71) Applicant: Intel Corporation, Santa Clara, CA (US)

(72) Inventors: Digvijay A. Raorane, Chandler, AZ (US); Debendra Mallik, Chandler, AZ (US)

(73) Assignee: Intel Corporation, Santa Clara, CA (US)

(21) Appl. No.: 16/462,908

(22) PCT Filed: Dec. 27, 2016
(86) PCT No.: PCT/US16/68754

§ 371 Date: May 21, 2019

(51) Int. Cl. H01L 23/522; H01L 25/18; H01L 23/00; H01L 23/528; H01L 23/48; H01L 21/768

(52) U.S. Cl. CPC H01L 23/5226; H01L 25/18; H01L 24/09; H01L 24/17; H01L 2924/15311; H01L 23/481; H01L 21/76898; H01L 2924/381; H01L 23/5283

(57) ABSTRACT

An apparatus is provided comprising: first die, wherein a first plurality of interconnect structures is formed on the first die; one or more layers, wherein a first surface of the one or more layers is attached to the first plurality of interconnect structures; a second plurality of interconnect structures formed on a second surface of the one or more layers; and a second die, wherein a third plurality of interconnect structures is formed on the second die, wherein a first interconnect structure of the first plurality of interconnect structures is electrically connected to a second interconnect structure of the second plurality of interconnect structures through the one or more layers, and wherein the first die is mounted on the second die such that the second interconnect structure of the second plurality of interconnect structures is attached to a third interconnect structure of the third plurality of interconnect structures.

### BACKGROUND

In a semiconductor package, a first die can be mounted on a second die in a flip chip configuration. For example, first bumps of the first die can be attached to second bumps of the second die via solder.

In some examples, however, a configuration (e.g., a layout, a pitch, etc.) of the first bumps of the first die can be different from the configuration of the second bumps of the second die. In such examples, conventionally, the first die may not be mounted on the second die. Reconfiguring the bumps of either the first die or the second die can be difficult, time consuming, impractical, and/or costly.

In another example where a third die is to be mounted on a fourth die in a flip chip configuration, the third die can be designed for a wire bonding configuration. Accordingly, conventionally, the third die may not be mounted on the fourth die in the flip chip configuration.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a cross-section view of a partial semiconductor package that is to include stacked first and second semiconductor dies, where a pitch of an array of interconnect structures of the first die is different from a pitch of an array of interconnect structures of the second die, according to some embodiment.

FIG. 2 illustrates a cross-section view of a partial semiconductor package that is to include stacked first and second semiconductor dies, where a pitch of interconnect structures of the first die is less than a pitch of interconnect structures of the second die, according to some embodiment.

FIGS. 3A-3F illustrates a process of mounting a first die on a second die, where a pitch of interconnect structures of the first die is less than a pitch of interconnect structures of the second die, according to some embodiments.

FIG. 4 illustrates a package in which a first die is mounted on a second die, where a pitch of interconnect structures of the first die is higher than a pitch of interconnect structures of the second die, according to some embodiments.

FIGS. 5A-5E illustrate another process of mounting a first die on a second die, where a pitch of interconnect structures of the first die is less than a pitch of interconnect structures of the second die, according to some embodiments.

FIG. 6 illustrates another package in which a first die is mounted on a second die, where a pitch of interconnect structures of the first die is higher than a pitch of interconnect structures of the second die, according to some embodiments.

FIGS. 7A-7G illustrate a process of mounting a first die on a second die, where a pitch of interconnect pads of the first die is different from a pitch of interconnect structures of the second die, according to some embodiments.

FIGS. 8A-8G illustrate a process of mounting a first die on a second die in a flip-chip configuration, where the first die is originally configured for wire bonding, according to some embodiments.

FIG. 9 illustrates a package in which a first die in stacked on a second die, where a number of interconnect structures of the first die that are to be interconnected is different from a number of interconnect structures of the second die that are to be interconnected, according to some embodiments.

FIG. 10 illustrates a flowchart depicting a method for mounting a first die on a second die, where a pitch of interconnect structures of the first die is less than a pitch of interconnect structures of the second die, according to some embodiments.

FIG. 11 illustrates a computing device in which a first die is stacked on a second die in a flip chip configuration, where the interconnect structures of the first and second dies are dissimilar, according to some embodiments.

### DETAILED DESCRIPTION

In some embodiments, a first die is to be mounted on a second die in a flip-chip configuration. For example, a first plurality of bumps of the first die is to be attached to a second plurality of bumps of the second die. However, in some examples, a pitch and/or a layout of the first plurality of bumps can be different from a pitch and/or a layout of the second plurality of bumps.

In some embodiments, in such a situation, an intervening one or more layers can be formed underneath the first plurality of bumps of the first die. Subsequently, a third plurality of bumps can be formed underneath the one or more layers. Individual bump of the third plurality of bumps may be electrically connected to a corresponding bump of the first plurality of bumps. In some embodiments, the pitch and layout of the third plurality of bumps can be different from those of the first plurality of bumps. For example, the pitch and layout of the third plurality of bumps can substantially match with those of the second plurality of bumps of the second die. Subsequently, the first die is mounted on the second die, e.g., such that the third plurality of bumps are correspondingly attached to the second plurality of bumps of the second die.

There are many technical effects of the various embodiments. For example, the techniques described herein can be used to mount a first die on a second die, even though the two dies have dissimilar pitch and/or layout of bump arrays. In some examples and as discussed herein below in further details, the techniques described herein can also be used to mount a first die on a second die in a flip-chip configuration, e.g., even if the first die is originally designed for wire bonding (e.g., the first die can have bond pads arranged on a periphery of the first die, and may not have bump pads for flip-chip mounting). Accordingly, the techniques described herein can be used to avoid costly and time consuming re-designing of the bump arrays or pads in the first die or the second die. Other technical effects will be evident from the various embodiments and figures.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.” The terms “substantially,” “close,” “approximately,” “near,” and “about,” generally refer to being within +/−10% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left.” “right,” “front” “back.” “top,” “bottom,” “over,” “under,” and the like in the description and in the claims, if any, are used for descriptive purposes and not necessarily for describing permanent relative positions.

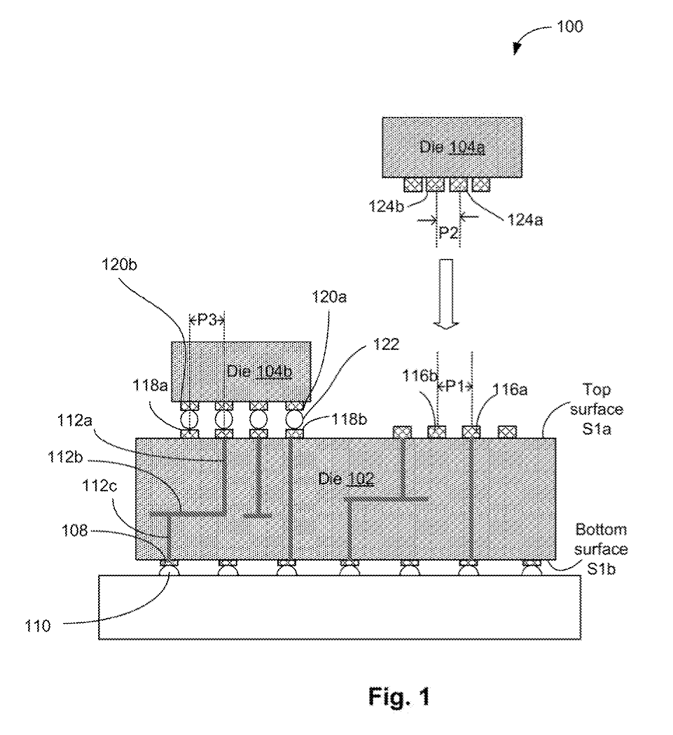

FIG. 1 illustrates a cross-section view of a partial semiconductor package 100 (henceforth also referred to as “package 100”) that is to include stacked semiconductor dies (henceforth referred to as “dies”) 102, 104a, and 104b, where a pitch of an array of interconnect structures of the die 102 is different from a pitch of an array of interconnect structures of the die 104a, according to some embodiment. The die 102, for example, forms a bottom die in the package 100, and the dies 104a and 104b are configured to be stacked on top of the die 102. A top surface and a bottom surface of the die 102 are labeled respectively as S1a and S1b in FIG. 1. In some embodiments, the package 100 is referred to as a partial package because, for example, the die 104a is not yet stacked on the die 102, e.g., for reasons discussed herein later.

In some embodiments, the dies 102, 104a, and 104b can be any appropriate integrated circuits. For example, individual ones of the dies 102, 104a, 104b can be a processor, a system on a chip (SOC), a memory, an application specific circuit (ASIC), a modem, a baseband processor, a RF (radio frequency) IC, some combination of such functions, and/or the like. In some embodiments, one or more top dies of the package 100 (e.g., one or both the dies 104a or 104b) can be memory dies, while the bottom die 102 can be a processor.

The package 100 comprises a substrate 106. In some embodiments, the substrate 106 may be a Printed Circuit Board (PCB) composed of an electrically insulative material such as an epoxy laminate. For example, the substrate 106 may include electrically insulating layers composed of materials such as, phenolic cotton paper materials (e.g., FR-1), cotton paper and epoxy materials (e.g., FR-3), woven glass materials that are laminated together using an epoxy resin (FR-4), glass/paper with epoxy resin (e.g., CEM-1), glass composite with epoxy resin, woven glass cloth with polytetrafluoroethylene (e.g., PTFE CCL), or other polytetrafluoroethylene-based prepreg material.

In some embodiments, the bottom surface S1b of the die 102 comprises a plurality of interconnect structures 108, which are attached to the substrate 106 via, for example, substrate bumps or solders 110. Interconnect structures, for the purposes of this disclosure and unless mentioned otherwise, may refer to bumps, metal pillars (e.g., copper pillars), balls formed using metals, alloys, solderable material, or their combinations, etc.

The die 102 comprises a plurality of interconnect components 112a, 112b, 112c, etc., e.g., to provide electrical connection between various components of the package 100. Merely as an example, individual ones of the interconnect components 112a, 112b, 112c comprises traces, trenches, routing layers, through-silicon-vias (TSVs), ground planes, power planes, re-distribution layers (RDLs), and/or any other appropriate electrical routing features. Although the die 102 is likely to have many more of such interconnect components, all such interconnect components are not illustrated in FIG. 1 for purposes of illustrative clarity and in order to not obfuscate the teaching of this disclosure.

In some embodiments, the top surface S1a of the die 102 comprises a first plurality of interconnect structures 116a, 116b, etc. (henceforth referred to as interconnect structure 116 in singular, or interconnect structures 116 in plural). In some embodiments, the interconnect structures 116 may be arranged in a ball grid array (“BGA”) or other configuration.

In some embodiments, the top surface S1a of the die 102 comprises a second plurality of interconnect structures 118a, 118b, etc. (henceforth referred to as interconnect structure 118 in singular, or interconnect structures 118 in plural). In some embodiments, the interconnect structures 118 may be arranged in a ball grid array (“BGA”) or other configuration.

In some embodiments, a bottom surface of the die 104a comprises a plurality of interconnect structures 124a, 124b, etc. (henceforth referred to as interconnect structure 124 in singular, or interconnect structures 124 in plural). In some embodiments, the interconnect structures 124 may be arranged in a ball grid array (“BGA”) or other configuration.

In some embodiments, a bottom surface of the die 104b comprises a plurality of interconnect structures 120a, 120b, etc. (henceforth referred to as interconnect structure 120 in singular, or interconnect structures 120 in plural). In some embodiments, the interconnect structures 120 may be arranged in a ball grid array (“BGA”) or other configuration.

Although not illustrated in FIG. 1, each of the interconnect structures 116, 118, 120, and 124 is attached to a corresponding pad (e.g., a bump pad) within the corresponding die. Merely as an example, the interconnect structure 116a is attached to a pad (e.g., a bump pad) which is formed, for example, on the top surface S1a of the die 102.

In a die, a pitch of the interconnect structures refers to a distance between a mid-section of a first interconnect structure (or an attached first bump pad) and a mid-section of an immediate adjacent second interconnect structure (or an attached second bump pad) that is nearest to the first interconnect structure. Merely as an example, a mid-section of the interconnect structure 116a of the die 102 is at a distance P1 from a mid-section of the interconnect structure 116b, where the interconnect structure 116b is immediate adjacent and nearest to the interconnect structure 116a. Accordingly, the pitch of the interconnect structures 116 of the die 102 is about P1. Similarly, a pitch of the interconnect structures 124 of the die 104a is about P2, where P2 is different from pitch P1, as illustrated in FIG. 1.

As also illustrated in FIG. 1, a pitch of the interconnect structures 118 of the die 102 is about P3, and a pitch of the interconnect structures 120 of the die 104b is also about P3 (in some examples, the pitch P3 can be substantially same as the pitch P1). Accordingly, in some embodiments, the interconnect structures 120 of the die 104b align over the corresponding interconnect structures 118 of the die 102. Such matching of the interconnect structures in the dies 102 and 104b are possible, for example, when the interconnect structures 120 of the die 104b are specifically designed to match the interconnect structures 118 of the die 102 (or, for example, when the interconnect structures 118 of the die 102 are specifically designed to match the interconnect structures 120 of the die 104b). Accordingly, the die 104b can be mounted on the top surface S1a of the die 102, e.g., via the interconnect structures 118, 120 and via solder balls 122. As illustrated in FIG. 1, the die 104b is mounted on the top surface S1a of the die 102 in a flip-chip configuration. In some embodiments, the die 104b is electrically coupled to the substrate 106 using one or more of the interconnect components 112 within the die 102. For example, the die 104b is electrically coupled to the substrate 106 using one or more TSVs, traces, routing layers, etc. within the die 102, although these are not illustrated in details in FIG. 1.

In some embodiments, the pitch P1 of the interconnect structures 116 of the die 102 is different from the pitch P2 of the interconnect structures 124 of the die 104a. For example, the pitch and/or layout of the interconnect structures 124 on the die 104a can be different from those of the interconnect structures 116 on the die 102. Accordingly, unlike the mounting of the die 104b on the die 102, the die 104a cannot be directly mounted on the die 102.

Difference in the pitches P1 and P2 can arise, for example, due to an incompatibility in the design of the dies 102 and 104a. For example, the die 102 can be designed and/or manufactured by a first manufacturer, whereas the die 104a can be designed and/or manufactured by a second manufacturer, thereby leading to the difference in layout and pitches of the interconnect structures 116 and 124. In another example, both the dies 102 and 104a can be designed and/or manufactured by the same manufacturer, but can be incompatible due to, for example, design considerations. Redesigning the layouts of the interconnect structures 116 and/or the interconnect structures 124 can be, for example, time consuming, costly, and/or impractical. This disclosure discusses various techniques to solve the issues arising from the inconsistencies in the layout and/or pitch of the interconnect structures in a first die and a second die (e.g., the dies 102 and 104a, respectively), to enable the second die to be mounted on the first die.

In some embodiments, if the die 104a is to be mounted on the interconnect structures 116 of the die 102, e.g., using one or more techniques discussed herein later, the die 104a can be electrically coupled to the substrate 106 using one or more of the interconnect components 112 within the die 102. For example, the die 104a can be electrically coupled to the substrate 106 using one or more TSVs, traces, routing layers, etc. within the die 102, although these components are not illustrated in detail in FIG. 1.

In some embodiments, the die 102 acts as an interposer between the dies 104a, 104b and the substrate 106. Accordingly, the die 102 is also referred to as an interposer die. For example, the interposer die 102 includes active and passive circuit components, such as transistors, logic gates, circuits, and/or any appropriate components that are generally included in a semiconductor die.

In some embodiments, the top side S1a of the die 102 may be the side of the die 102 commonly referred to as the “active” or “front” side of the die 102. In some embodiments, one or more transistors may be disposed at or near the top side S1a. The bottom side S1b of the die 102 may be commonly referred to as the “inactive” or “back” side of the die. In some embodiments, the interconnect structures 116 and 118 of the die 102 may be for electrically connecting the dies 104a and 104b to the substrate 106, e.g., through the interconnect components 112. In some embodiments, the interconnect structures 124 may be formed on an active or front side of the die 104a, and the interconnect structures 120 may be formed on an active or front side of the die 104b. In some embodiments, dies may be coupled with one another in a front-to-front, back-to-back, or side-to-side arrangement. In some embodiments, one or more additional dies may be coupled with the die 102 (e.g., in addition to the dies 104a and 104b). Some embodiments may lack die 104b. In some embodiments and although not illustrated in FIG. 1, additional dies may be stacked on top of the die 104a and/or the die 104b.

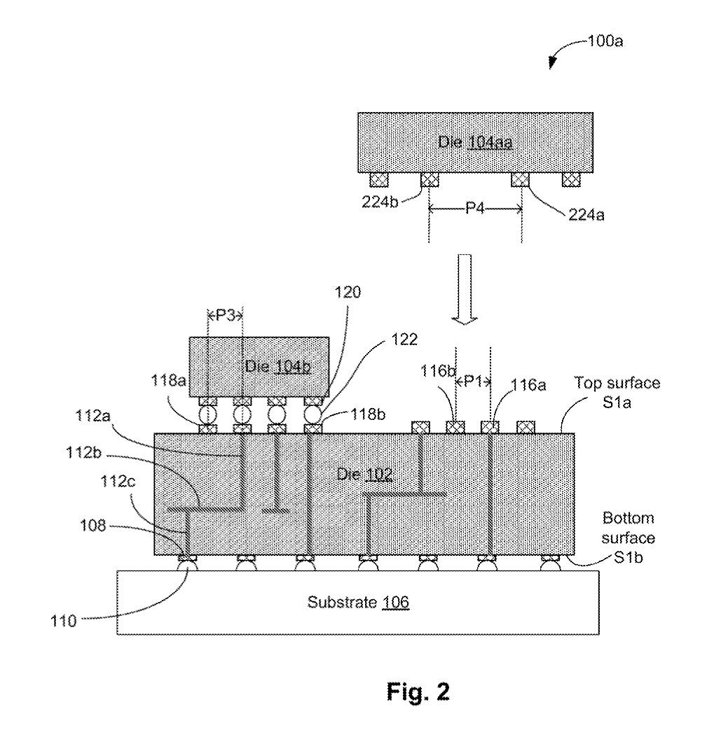

In FIG. 1, the pitch P1 of the die 102 is higher than the pitch P2 of the die 104a. However, in some example, the top die in the package can have a higher pitch than the bottom die. For example, FIG. 2 illustrates a cross-section view of a partial semiconductor package 100a (henceforth also referred to as “package 100a”) that is to include stacked semiconductor dies 102, 104aa, and 104b, where a pitch of the interconnect structures 116 of the die 102 is less than a pitch of interconnect structures 224 of the die 104aa, according to some embodiment. The packages 100 and 100a are at least in part similar, and many components are illustrated using similar labels. However, the die 104a in FIG. 1 is replaced by a die 104aa in FIG. 2. The die 104aa has a plurality of interconnect structures 224a, 224b, etc. (henceforth referred to as interconnect structure 224 in singular, or interconnect structures 224 in plural) which, for example, may be arranged in a BGA or other configuration. As illustrated, the interconnect structures 224 have a pitch of P4, which, for example, in higher than the pitch P1 of the interconnect structures 116. Accordingly, similar to FIG. 1, in FIG. 2 also it may not be possible to directly mount the die 104aa on the interconnect structures 116 of the die 102.

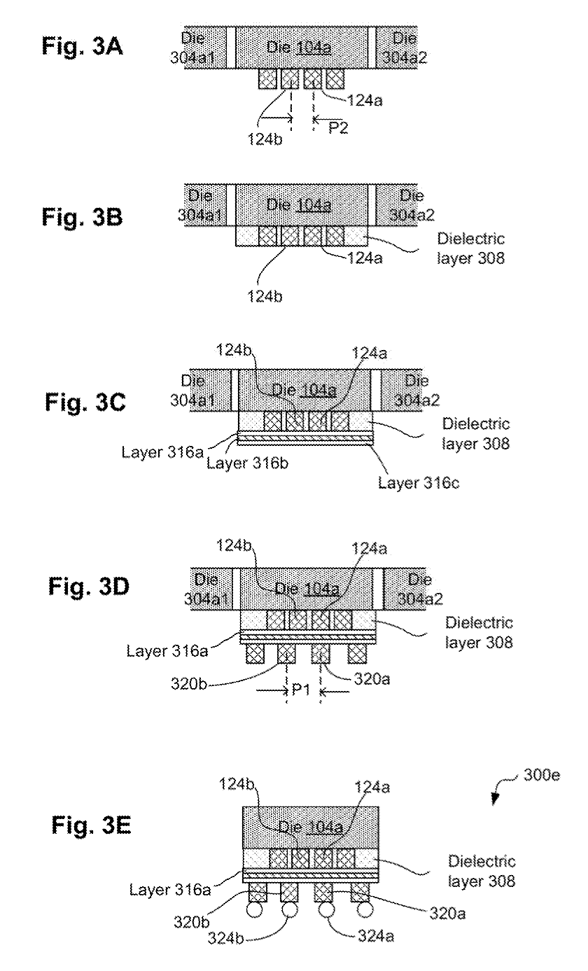

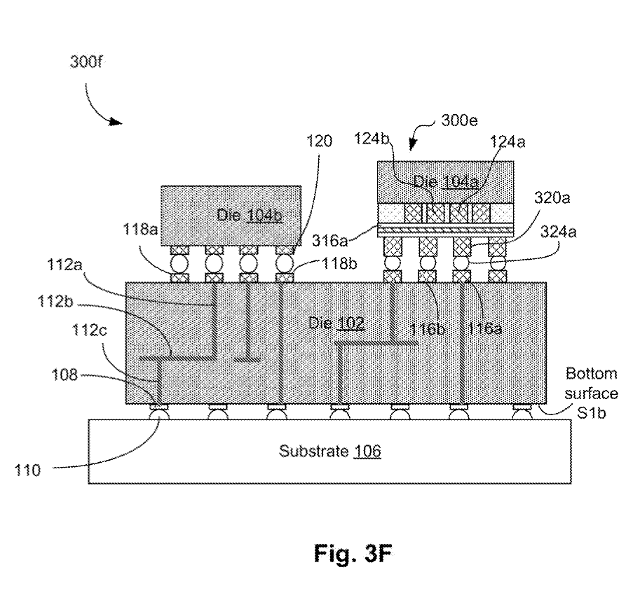

FIGS. 3A-3E illustrate a process of mounting a first die (e.g., the die 104a of FIG. 1) on a second die (e.g., the die 102 of FIG. 1), where a pitch (e.g., pitch P2) of the interconnect structures (e.g., interconnect structures 124) of the first die is less than a pitch (e.g., pitch P1) of the interconnect structures (e.g., interconnect structures 116) of the second die, according to some embodiments.

Referring to FIG. 3A, the die 104a is still attached to a corresponding wafer. Accordingly, the die 104a is still attached to other adjacent dies, e.g., dies 304a1 and 304a2, although the adjacent dies are not illustrated in detail in the figures. FIG. 3A illustrates interconnect structures 124 formed on a bottom surface of the die 104a. Although not illustrated in FIG. 3A, each of the interconnect structures 124 is attached to a corresponding pad (e.g., a bump pad) on the bottom surface of the die 104a. As discussed with respect to FIG. 1, the interconnect structures 124 have a pitch P2.

In FIG. 3B, a dielectric layer 308 is formed around the interconnect structures 124. The dielectric layer 308, for example, better insulates the interconnect structures 124 from each other, for mechanical strength, and/or heat dissipation purposes. In some embodiments, the dielectric layer 308 is flush with an open end of the interconnect structures 124 (e.g., the end of the interconnect structures 124 that is not attached to the die 104a), e.g., such that the open end of the interconnect structures 124 are exposed through the dielectric layer 308.

In FIG. 3C, one or more up layers 316 (e.g., layers 316a, 316b, 316c, discussed herein later) are deposited on the dielectric layer 308. In FIG. 3D, a plurality of interconnect structures 320a, 320b, etc. (henceforth referred to as interconnect structure 320 in singular, or interconnect structures 320 in plural) are deposited on the layers 316. In some embodiments, the interconnect structures 320 may be arranged in a ball grid array (“BGA”) or other configuration.

In some embodiments, each interconnect structure 320 is electrically connected to a corresponding interconnect structure 124 through the layers 316. For example, a top surface of the layers 316 is attached to the interconnect structures 124, a bottom surface of the layers 316 is attached to the interconnect structures 320, and the layers 316 selectively connect an interconnect structure 124 to a corresponding interconnect structure 320 (e.g., the connections through the layers 316 are not illustrated in FIG. 3D). For example, the interconnect structure 320a is electrically connected to the interconnect structure 124a through the layers 316, the interconnect structure 320b is electrically connected to the interconnect structure 124b through the layers 316, and so on.

In some embodiments, the layers 316 comprises, for example, alternative layers of dielectric (or insulating) material and metal (or conductive). The dielectric layer, for example, comprises molding compound, an adhesive based dielectric layer (such as Ajinomoto Build-up Film (ABF)), or another appropriate dielectric layer. Although only three layers 316a, 316b, 316c are illustrated in FIGS. 3C and 3D, there may be more or less number of such layers. The layers 316, for example, comprises traces, re-distribution layers (RDL), TMVs, routing structures, etc., using which the interconnect structures 124 and 320 are electrically connected.

In some embodiments, the pitch of the interconnect structures 320 is about P1, which may be substantially same as the pitch of the interconnect structures 116 of the die 102. Thus, the layers 316 forms a mapping between the interconnect structures 124 with the smaller pitch P2 to the interconnect structures 320 with the higher pitch P1. In some embodiments, additionally, a layout of the interconnect structures 320 can be different from the layout of the interconnect structures 124. For example, the layout and the pitch of the interconnect structures 320 can be designed to match those of the interconnect structures 116 of the die 102.

In FIG. 3E, a plurality of attachment component, e.g., a plurality of solder balls 324 (e.g., solder balls 324a, 324b, etc.) are deposited on the interconnect structures 320. For example, each of the plurality of solder balls 324 is deposited on a corresponding one of the interconnect structures 320 (e.g., the solder ball 324a is deposited on the interconnect structure 320a, the solder ball 324b is deposited on the interconnect structure 320b, and so on). Also, in FIG. 3E, the wafer of the die 104a is singulated, e.g., such that the die 104a is separated from the adjacent dies 304a1 and 304a2.

In some embodiments and although not illustrated in the figures, the solder balls 324 can be formed directly on the bottom surface of the layers 316. For example, in such embodiments, the interconnect structures 320 may be absent, and the solder balls are formed directly on connection pads formed on the bottom surface of the layers 316.

In some embodiments, the die 104a, along with the layers 316, the interconnect structures 124, 320, and the solder balls 324, is also referred to herein as a package 300e. FIG. 3E, for example, illustrates the package 300e (e.g., the components illustrated in FIG. 3E is included in the package 300e).

In some embodiments, in FIG. 3F, the die 104a, along with the layers 316, the interconnect structures 124, 320, and the solder balls 324 (e.g., the package 300e), is mounted on the interconnect structures 116 of the die 102. For example, because the layout and the pitch of the interconnect structures 320 of the die 104a match those of the interconnect structure 116 of the die 102, the die 104a can now be mounted on the die 102.

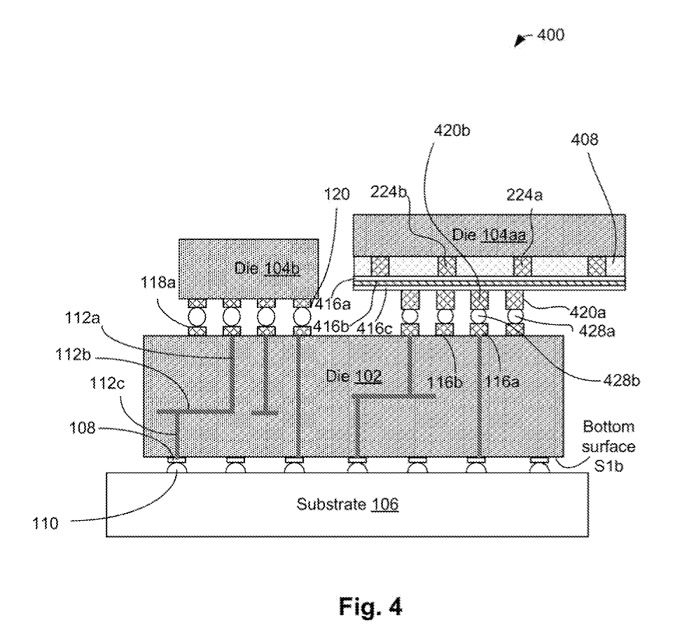

FIGS. 3A-3F illustrate a situation where the layers 316 increase the pitch P2 of the interconnect structures 124 to the pitch P1 of the interconnect structures 320. However, in some embodiments, such layers can take the opposite role, e.g., decrease a pitch of the interconnect structures of a die, e.g., decrease the pitch P4 of the interconnect structures 224 of the die 104aa of FIG. 2, e.g., as illustrated in below FIG. 4.

FIG. 4 illustrates a package 400 in which a first die 104aa (eg., as illustrated in FIG. 2b) is mounted on a second die 102, where a pitch (e.g., the pitch P4 of FIG. 2) of interconnect structures 224 of the first die 104aa is higher than a pitch (e.g., pitch P1) of interconnect structures 116 of the second die 102, according to some embodiments. The 104aa has interconnect structures 224 formed on a bottom surface of the die 104aa, where the interconnect structures 224 are encapsulated by dielectric layer 408. Layers 416 (e.g., comprising the layers 416a, 416b, and 416c) form selective connection between the interconnect structures 224 (e.g., which are on a top surface of the layers 416) and interconnect structures 420 (e.g., which are on a bottom surface of the layers 416). The interconnect structures 224 has a pitch of P4 (e.g., as discussed with respect to FIG. 2), while the interconnect structures 420 (e.g., interconnect structures 420a, 420b) have a pitch of P1. The pitch and layout of the interconnect structures 420, for example, matches those of the interconnect structure 116 of the die 102. Accordingly, in some embodiments, the interconnect structures 420 are connected to the interconnect structures 116, e.g., via solder balls 428.

The die 104aa including the dielectric layer 408, the layers 416, the interconnect structures 224, and the solder balls 428, as illustrated in FIG. 4, is similar to the die 104a and the corresponding components of FIG. 3F. The difference between these two figures, for example, is that in FIG. 3F, the pitch is increased from P2 to P1, whereas in FIG. 4, the pitch is decreased from P4 to P1. Accordingly, the formation of the package 400 would be evident to those skilled in the art, e.g., based on FIGS. 3A-3F and associated discussion, and hence, the formation of the package 400 will not be discussed in further details herein.

Referring again to FIGS. 3A-3F, these figures illustrate a manner to form the package 300e, which is then mounted on the die 102. In some embodiments, there may be many other ways to prepare the 104a for mounting on the die 102.

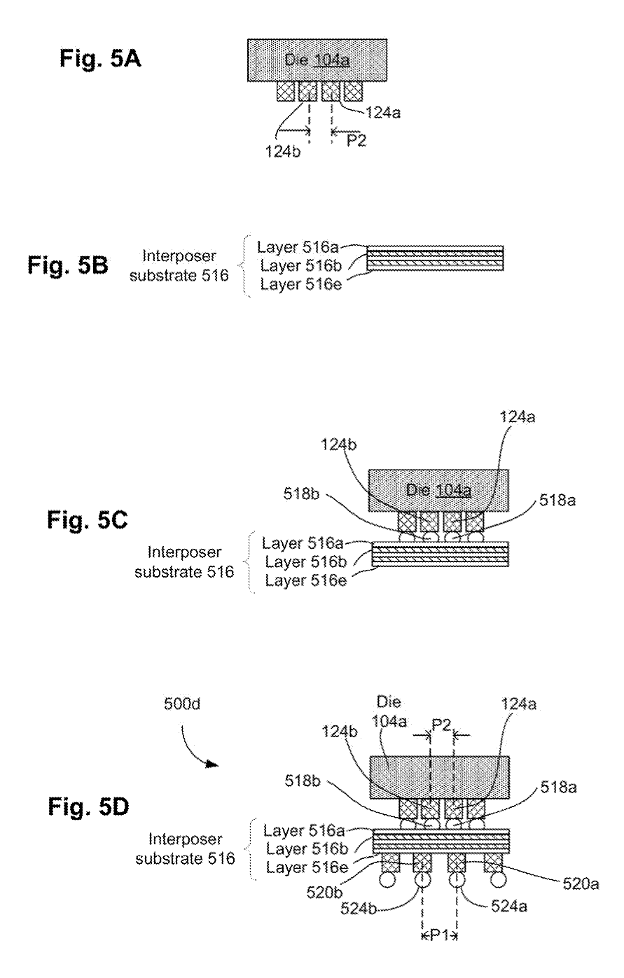

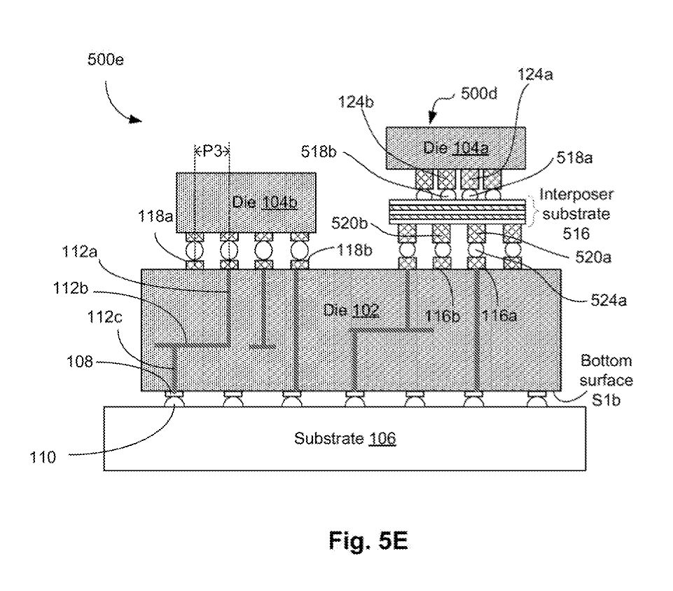

FIGS. 5A-5E illustrate another process of mounting a first die (e.g., the die 104a of FIG. 1) on a second die (e.g., the die 102 of FIG. 1), where a pitch (e.g., pitch P2) of the interconnect structures (e.g., interconnect structures 124) of the first die is less than a pitch (e.g., pitch P1) of the interconnect structures (e.g., interconnect structures 116) of the second die, according to some embodiments.

Referring to FIG. 5A, unlike FIG. 3A, in some embodiments, in FIG. 5A the die 104a may have already been singulated from the wafer, and is a stand-alone die (although in some other embodiments, the die 104a can still be in the wafer stage). In some embodiments, interconnect structures 124 may formed on a bottom surface of the die 104a. Although not illustrated in FIG. 5A, each of the interconnect structures 124 may be attached to a corresponding pad (e.g., a bump pad) on the bottom surface of the die 104a. As discussed with respect to FIG. 1, the interconnect structures 124 have a pitch P2.

In some embodiments, unlike FIG. 3, in FIGS. 5A and 5B, no dielectric layer is formed to encapsulate the interconnect structures 124 (e.g., although in some other embodiments, such a dielectric layer may also be formed).

In FIG. 5B, an interposer substrate (henceforth also referred to as “substrate”) 516 is formed, where the substrate 516 comprises one or more layers 516 (e.g., layers 516a, 516b, . . . , 516e). The substrate 516 is discussed herein later in further details. In some embodiments, the substrate 516 of FIG. 5B can be formed independent of forming the die 104a of FIG. 5A.

In FIG. 5C, the die 104a, including the interconnect structures 124, is attached to the substrate 516 using solder 518 (e.g., solder 518a, 518b, etc.). In some embodiments, the interconnect structures 124 are attached to a top surface of the substrate 516 (e.g., a top surface of the layer 516a).

In FIG. 5D, a plurality of interconnect structures 520a, 520b, etc. (henceforth referred to as interconnect structure 520 in singular, or interconnect structures 520 in plural) are deposited on a bottom surface of the substrate 516 (e.g., on a bottom surface of the layer 516e). In some embodiments, the interconnect structures 520 may be arranged in a ball grid array (“BGA”) or other configuration. Furthermore, in FIG. 5D, a solder 524 is attached to a corresponding interconnect structure 520 (e.g., a solder 524a is attached to the interconnect structure 520a, a solder 524b is attached to the interconnect structure 520b, and so on).

In some embodiments, each interconnect structure 520 is electrically connected to a corresponding interconnect structure 124 through the substrate 516. For example, the top surface of the substrate 516 is attached to the interconnect structures 124, the bottom surface of the substrate 516 is attached to the interconnect structures 520, and the substrate 516 selectively connect an interconnect structure 124 to a corresponding interconnect structure 520 (e.g., the connections through the layers 516 are not illustrated in FIGS. 5B-5D). For example, the interconnect structure 520a is electrically connected to the interconnect structure 124a through the substrate 516 and the solder 518a, the interconnect structure 520b is electrically connected to the interconnect structure 124b through the substrate 516 and the solder 518b, and so on.

In some embodiments, the substrate 516 comprises, for example, alternative layers of dielectric (or insulating) material layer and metal (or conductive) layer. Although only five layers 516a, . . . 516e are illustrated in FIGS. 5C and 5D, there may be more or less number of such layers. The substrate 516, for example, comprises traces, re-distribution layers (RDL), TSVs, routing structures, etc., using which the interconnect structures 124 and 520 are electrically connected.

In some embodiments, the pitch of the interconnect structures 520 is about P1, which may be substantially same as the pitch of the interconnect structures 116 of the die 102. On the other hand, the pitch of the interconnect structures 124 is about P2. Thus, the substrate 516 forms a mapping between the interconnect structures 124 with the smaller pitch P2 to the interconnect structures 520 with the higher pitch P1. In some embodiments, additionally, a layout of the interconnect structures 520 can be different from the layout of the interconnect structures 124. For example, the layout and the pitch of the interconnect structures 520 can be designed to match those of the interconnect structures 116 of the die 102.

In some embodiments and although not illustrated in FIG. 5D, the solder balls 524 may be formed directly on the bottom surface of the substrate 516. For example, in such embodiments, the interconnect structures 520 may be absent, and the solder balls may be formed directly on connection pads formed on the bottom surface of the layer 516e, where a pitch of the solder balls 524 may be about P1.

In some embodiments, the die 104a, along with the substrate 516, the interconnect structures 124, 520, and the solder balls 518, 524, is also referred to herein as a package 500d. FIG. 5D, for example, illustrates the package 500d (e.g., the components illustrated in FIG. 5D is included in the package 500d).

In some embodiments, in FIG. 5E, the package 500d of FIG. 5D (e.g., comprising the die 104, the substrate 516, the interconnect structures 124, 520, and the solder balls 518, 524) is mounted on the interconnect structures 116 of the die 102 to form a package 500e. For example, because the layout and the pitch of the interconnect structures 520 of the die 104a match those of the interconnect structure 116 of the die 102, the die 104a can now be mounted on the die 102.

In some embodiments, the interconnect structures 518 comprises a first type of solder, and the interconnect structures 520 comprises a second type of solder that is different from the first type of solder.

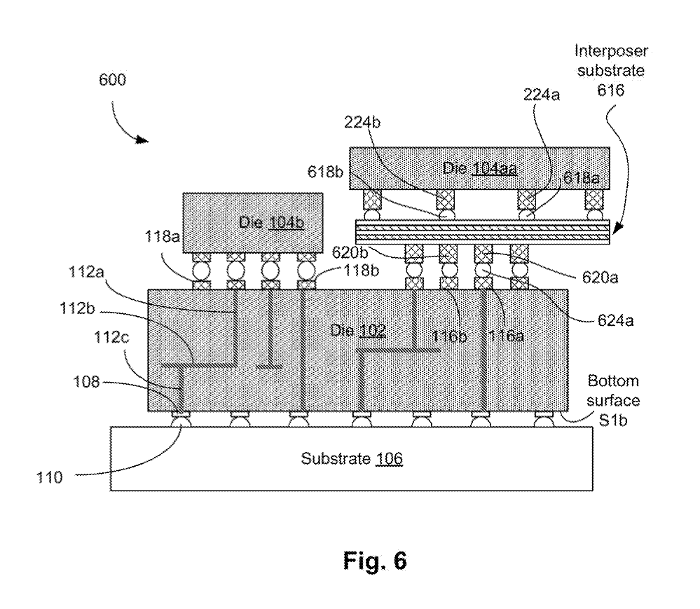

FIGS. 5A-5E illustrate a situation where the substrate 516 increases the pitch P2 of the interconnect structures 124 to the pitch P1 of the interconnect structures 520. However, in some embodiments, such a substrate can take the opposite role, e.g., decrease a pitch of the interconnect structures of a die, e.g., decrease the pitch P4 of the interconnect structures 224 of the die 104aa of FIG. 2, e.g., as illustrated in below FIG. 6.

FIG. 6 illustrates a package 600 in which a first die 104aa is mounted on a second die 102, where a pitch (e.g., pitch P4) of interconnect structures 224 of the first die 104aa is higher than a pitch (e.g., pitch P1) of interconnect structures 116 of the second die 102, according to some embodiments. The die 104aa has interconnect structures 224 formed on a bottom surface of the die 104aa, which has a pitch of P4, e.g., as illustrated in FIG. 2. An interposer substrate 616 connects the interconnect structures 224 with corresponding interconnect structures 620, e.g., via solder 618. The pitch and layout of the interconnect structures 620, for example, match those of the interconnect structures 116 of the die 102. Accordingly, in some embodiments, the interconnect structures 620 are connected to the interconnect structures 116, e.g., via solder balls 624.

The die 104aa, the interposer substrate 616, the interconnect structures 620, and the solder balls 618, 624, as illustrated in FIG. 6, are similar to the corresponding components in the package 500d of FIG. 5D. The difference between these two figures, for example, is that in FIG. 5D, the pitch is increased from P2 to P1 using the substrate 516, whereas in FIG. 6, the pitch is decreased from P4 to P1 using the substrate 616. Accordingly, the formation of the package 600 would be evident to those skilled in the art, e.g., based on FIGS. 5A-5E and associated discussion, and hence, the formation of the package 600 will not be discussed in further details herein.

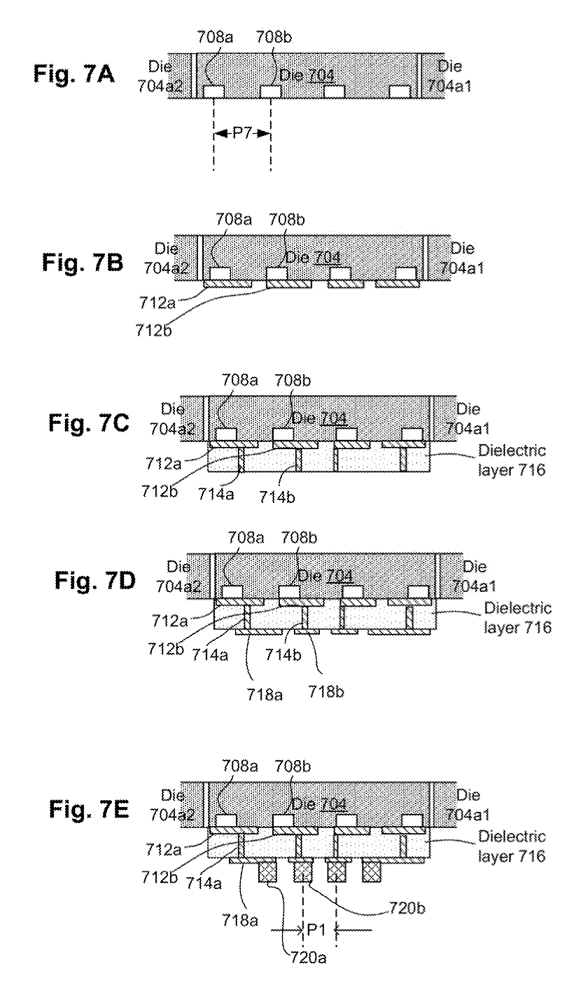

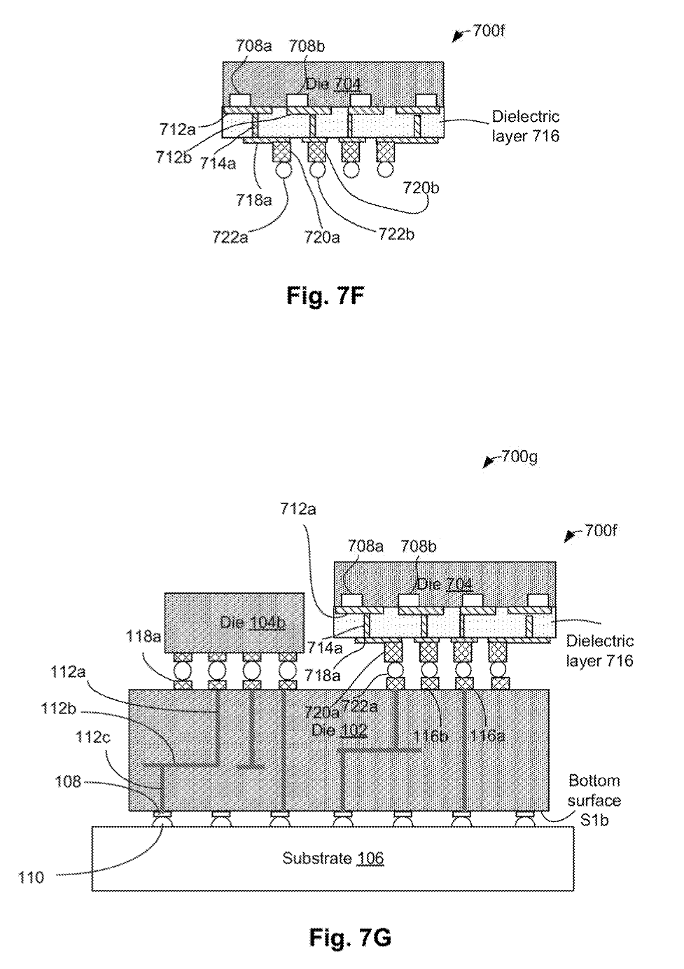

FIGS. 7A-7G illustrate a process of mounting a die 704 on the die 102, where a pitch P7 of interconnect pads 708 of the die 704 is different from the pitch of the interconnect structures 116 of the die 102, according to some embodiments. Referring to FIG. 7A, the die 704 comprises the interconnect pads 708a, 708b, etc., generally referred to as interconnect pad 708 in singular, and interconnect pads 708 in plural. The interconnect pads 708 are, for example, bump pads or connection pads where interconnect structures, bumps, metal pillars (e.g., copper pillars), etc., are to be formed (although any interconnect structures are not formed on the interconnect pads 708). In some embodiments, the interconnect pads 708 are arranged in a BGA configuration, although another configuration may also be used. In some embodiments where the interconnect pads 708 are bump pads, the die 704 including the interconnect pads 708 is designed to be mounted in a flip-chip configuration. In some embodiments, the interconnect pads 708 are disposed on a bottom surface of the die 704. In some embodiments, the interconnect pads 708 have a pitch of P7, which, for example, is higher than the pitch P1 of the interconnect structures 116 of the die 102 of FIG. 1.

In some embodiments, in FIG. 7A, the die 704 is still attached to a corresponding wafer. Accordingly, the die 704 has other adjacent dies, e.g., dies 704a1 and 704a2, although the adjacent dies are not illustrated in detail in the figures.

In FIG. 7B, a plurality of metal connections 712a, 712b, etc. are formed on the interconnect pads 708. The metal connections 712 are formed, for example, by forming a metal layer on the bottom surface of the die 704, and selectively etching the metal layer to form the metal connections 712.

In FIG. 7C, the metal connections 712 are encapsulated using an appropriate dielectric layer 716, e.g., to avoid electrical short between the metal connections 712, for mechanical strength, and/or heat dissipation purposes.

In some embodiments, in FIG. 7C, a plurality of vias, e.g., trough mold vias (TMVs) 714 (e.g., TMV 714a, TMV 714b, etc.) are formed through the dielectric layer 716. For example, a plurality of holes is formed in the dielectric layer 716, and which are then filed with conductive material (e.g., metal, metal alloy, or other conductive layer) to form the TMVs 714a, 174b, etc. Each TMV 714 (e.g., the TMV 714a) is connected to a corresponding metal connection 712 (e.g., the metal connection 712a). In some embodiments, instead of a TMV 714, a conducive trace, a redistribution layer, or another appropriate routing structure can be formed within the dielectric layer 716.

In some embodiments, in FIG. 7D, each of a plurality of interconnect pads 718 (e.g., interconnect pads 718a, 718b, etc.) are formed on a corresponding one of the TMVs 714. For example, a first end of a TMV 714 (e.g., the TMV 714a) is attached to a corresponding metal connection 712 (e.g., the metal connection 712a) and a second end of the TMV 714 is attached to a corresponding interconnect pad 718 (e.g., the interconnect pad 718a).

In FIG. 7E, a plurality of interconnect structures 720 (e.g., interconnect structure 720a, interconnect structure 720b, etc.), generally referred to as interconnect structure 720 in singular, and interconnect structures 720 in plural, are formed on the interconnect pads 718. For example, the interconnect structure 720a is formed on the interconnect pad 718a, the interconnect structure 720b is formed on the interconnect pad 718b, and so on. In some embodiments, the pitch P1 and the layout of the interconnect structures 720 match with those of the interconnect structures 116 of the die 102.

In FIG. 7F, each of a plurality of solder balls 722a, 722b, etc., is attached to a corresponding one of the interconnect structures 720. Furthermore, the wafer of the die 704 is singulated, and the die 704 is separated from the adjacent dies 704a1 and 704a2, to form a package 700f.

In FIG. 7G, the package 700f of FIG. 7F is mounted on the die 102 (e.g., instead of the die 104a). Because the pitch and the layout of the interconnect structures 720 of the die 704 match those of the interconnect structures 116 of the die 102, the package 700f can be mounted on the die 102 to form a package 700g.

FIGS. 7A-7G illustrate a situation where the metal connections 712, the TMVs 714, and the interconnect pads 718 reduces the pitch P7 of the interconnect pads 708 to the pitch P1 of the interconnect structures 720. In some embodiments, similar metal connections, TMVs, and interconnect pads RDLs may also be used to increase a pitch of interconnect pads of a die. Such components and a resulting package will be readily understood by those skilled in the art, e.g., based on the teachings of this disclosure, and hence, such a package is not separately discussed herein.

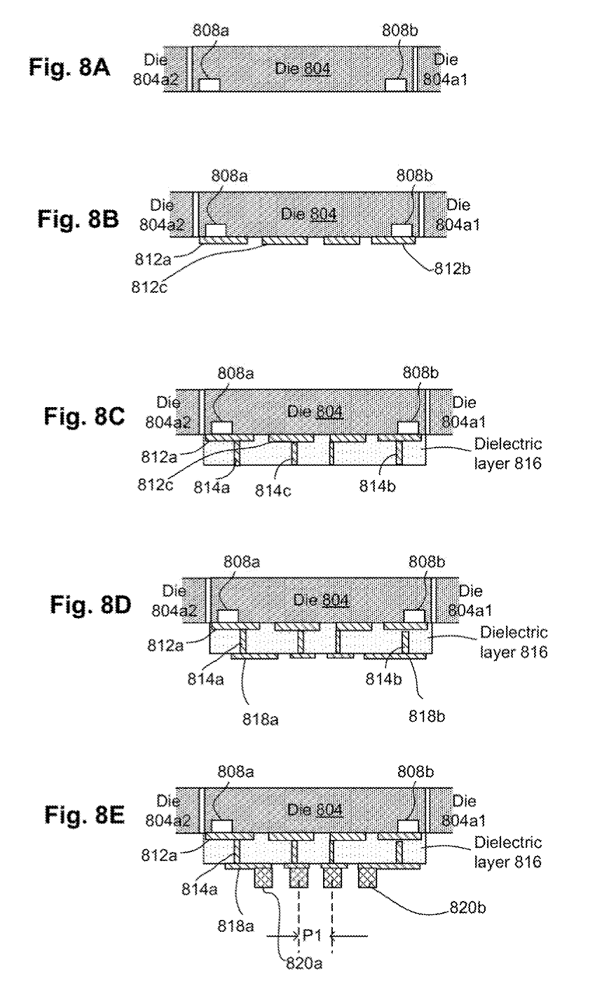

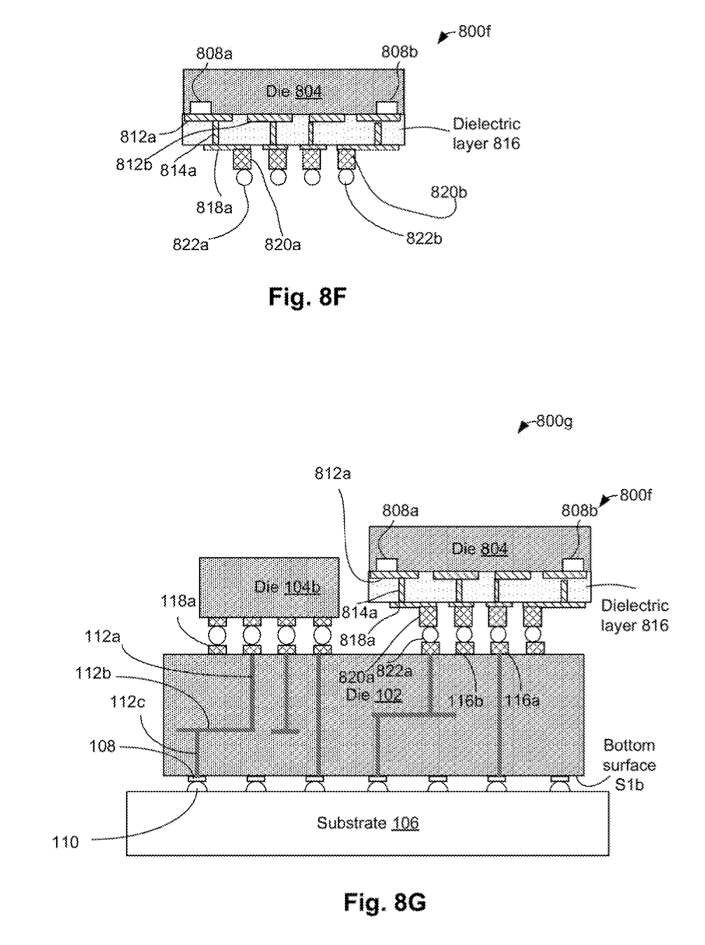

In FIGS. 7A-7G, the interconnect pads 708, for example, are bump pads designed for a flip-chip mounting of the die 704, and the die 704 is mounted on the die 102 in a flip-chip configuration. However, in some embodiments, it may be desirable to mount a first die on a second die in a flip-chip configuration, where the first die is originally configured for wire bonding. FIGS. 8A-8G illustrates a process of mounting a first die (e.g., a die 804) on a second die (e.g., the die 102) in a flip-chip configuration, where the first die 804 is originally configured for wire bonding, according to some embodiments.

Referring to FIG. 8A, the die 804 comprises the interconnect pads 808a, 808b, etc., generally referred to as interconnect pad 808 in singular, and interconnect pads 808 in plural. The interconnect pads 808 are, for example, bond pads or connection pads that are designed for wire bonding. In some embodiments, the interconnect pads 808 are arranged along a periphery of the die 804, e.g., as is generally customary for dies designed for wire-bonding.

In some embodiments, the interconnect pads 808 are disposed on a bottom surface of the die 804. Although a plurality of interconnect pads 808 are disposed on a bottom surface of the die 804, only two interconnect pads 808a and 808b are visible in the cross section view of FIG. 8A. In some embodiments, the layout of the interconnect pads 808 is different from the layout of the interconnect structures 116 of the die 102 of FIG. 1.

In some embodiments, in FIG. 8A, the die 804 is still attached to a corresponding wafer. Accordingly, the die 804 has other adjacent dies, e.g., dies 804a1 and 804a2, although the adjacent dies are not illustrated in detail in the figures (although in some other embodiments, in FIG. 8A, the die 804 has already been singulated and separated from the adjacent dies).

In FIG. 8B, a plurality of metal connections 812 (e.g., metal connections 812a, 812b, 812c, etc.) are formed on the bottom surface of the die 804. The metal connections 812 are formed, for example, by forming a metal layer on the bottom surface of the die 804, and selectively etching the metal layer to form the metal connections 812.

In some embodiments, although not illustrated in FIG. 8B each metal connection 812 is electrically connected to a corresponding interconnect pad 808. For example, the interconnect pad 808a is connected to the metal connection 812a, the interconnect pad 808b is connected to the metal connection 812b, an interconnect pad 808c (not illustrated in the figures) is connected to the metal connection 812c, and so on. The interconnect pad 808c is connected to the metal connection 812c, e.g., via one or more of traces, redistribution layers, routing layers, etc., which are not visible in the cross-sectional view of FIG. 8B.

In FIG. 8C, the metal connections 812 are encapsulated using an appropriate dielectric layer 816, e.g., to avoid electrical short between the metal connections 812, for mechanical strength, and/or heat dissipation purposes. Furthermore, in some embodiments, in FIG. 8C, a plurality of vias, e.g., trough mold vias (TMVs) 814 (e.g., TMV 814a, TMV 814b, etc.) are formed through the dielectric layer 816. In some embodiments, in FIG. 8D, each of a plurality of interconnect pads 818 (e.g., interconnect pads 818a, 818b, etc.) is formed on a corresponding one of the TMVs 814. In FIG. 8E, a plurality of interconnect structures 820 (e.g., interconnect structure 820a, interconnect structure 820b, etc.), generally referred to as interconnect structure 820 in singular, and interconnect structures 820 in plural, are formed on the interconnect pads 818. In FIG. 8F, each of a plurality of solder balls 822a, 822b, etc., is attached to a corresponding one of the interconnect structures 820. Furthermore, in some embodiments, the wafer of the die 804 is singulated, and the die 804 is separated from the adjacent dies 804a1 and 804a2, to form a package 800f. In FIG. 8G, the package 800f of FIG. 8F is mounted on the die 102 (e.g., instead of the die 104a). Because the pitch and the layout of the interconnect structures 820 of the die 804 match those of the interconnect structures 116 of the die 102, the package 800f can be mounted on the die 102 to form a package 800g.

Various operations discussed with respect to FIGS. 8B-8G will be readily evident to those skilled in the art, e.g., based on the discussion in the corresponding ones of FIGS. 7B-7G. Accordingly, the operations performed in FIGS. 8B-8G are not discussed in further details herein.

In FIGS. 3A-8G, various techniques have been discussed to mount a first die (e.g., dies 104a, 104aa, 704, or 804) on a second die (e.g., the die 102) in a flip-chip configuration, where the first die has interconnect structures (or interconnect pads) with a layout and pitch that are different from those of the interconnect structures of the second die. These techniques can also be applied for various other purposes.

Merely as an example, referring to FIG. 3F (although any other figure can also be used as an example), assume that the interconnect structures 124 of the die 104a are incompatible with the interconnect structure 116 of the die 102, e.g., from a metallurgical perspective. For example, the interconnect structure 124 can be formed using first metal that works with a first type of solder, whereas the interconnect structure 116 can be formed using second metal that works with a second type of solder. In such a case, even if it is assumed that the pitch and the layout of the interconnect structures 124 are same as those of the interconnect structure 116, the die 104a cannot be directly mounted on the die 102. This is because, for example, there may not be an appropriate solder that can be attached to both the interconnect structures 116 and 124. The metallurgical incompatibility between the interconnect structures 116 and 124, for example, can be solved using, in the context of FIG. 3F, the layers 316a, . . . , 316c. For example, in the package 300f of FIG. 3F, although the interconnect structures 116 and 124 may be incompatible, the material of the interconnect structures 320 can be selected such that the interconnect structures 320 and 116 are compatible. For example, the material of the interconnect structures 320 can be selected such that both the interconnect structures 320 and 116 can be attached to at least the second type of solder.

The teachings of this disclosure may be also used, for example, to solve incompatible geometry between interconnect structures of two different dies that are to be stacked. For example, again, referring to FIG. 3F, assume that the geometry of the interconnect structures 124 is different from that of the interconnect structures 116. For example, a width of the interconnect structure 124a may be relatively less, e.g., compared to a width of the interconnect structure 116a, thereby making it difficult to attach the interconnect structure 124a to the interconnect structure 116a directly via solder. Such an issue may arise in addition to, or instead of, a mismatch in the pitch and/or layout of the interconnect structures 116 and 124.

The incompatibility between the interconnect structures 116 and 124 due to the difference between the widths of these interconnect structures (or due to difference between a shape, a diameter, a height, etc. of these interconnect structures), for example, can be solved using, in the context of FIG. 3F, the layers 316a, . . . , 316c. For example, in the package 300f of FIG. 3F, although the interconnect structures 116 and 124 may be incompatible because of varying widths, the interconnect structures 320 can be designed such that the interconnect structures 320 and 116 are compatible. For example, the width of the interconnect structures 320 can be selected such that both the interconnect structures 320 and 116 can be attached to at least the second type of solder.

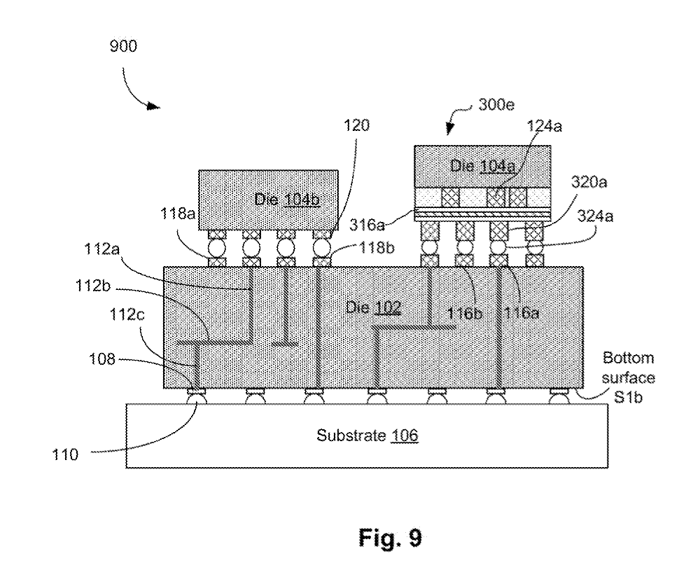

FIGS. 3A-8G have been discussed in the context of mismatch in layouts and/or pitches of the interconnect structures of a first die and the interconnect structures of a second die (or the interconnect pads of a first die and the interconnect structures of a second die). However, in addition to, or instead of, a difference in a layout and/or a pitch, there may be many other differences between the interconnect structures of the two dies. For example, a number of interconnect structures of the first die can be different from a number of interconnect structure of the second die. For example, FIG. 9 illustrates a package 900 in which a first die (e.g., the die 104a of FIG. 3F) in stacked on a second die (e.g., the die 102 of FIG. 3F), where a number of interconnect structures of the first die that are to be interconnected is different from a number of interconnect structures of the second die that are to be interconnected, according to some embodiments.

FIG. 9 is at least in part similar to the package 300f of FIG. 3F. However, in FIG. 9, the die 104a is assumed to have three interconnect structure 124, while the die 102 has four interconnect structure 116 to be connected to the die 104a (it is to be noted that numbers three and four are merely examples to illustrate a difference in the interconnect structures in the two dies, and a die is likely to include many more interconnect structures).

Although there are only three interconnect structures 124 in the die 104a, the package 300e has four interconnect structures 320 that match the number, layout and pitch of the interconnect structures 116 of the die 102. In an example (and although not illustrated in FIG. 9), each of three of the four interconnect structures 320 is electrically connected to a respective one of the three interconnect structures 124 (e.g., through the layers 316). A fourth interconnect structure 320, for example, is not electrically connected to any of the interconnect structures 124. The fourth interconnect structure 320, for example, can be floating, be connected to a ground plane (or a power plane) within the layers 316, etc. Thus, the layers 316 and the interconnect structure 320, for example, facilitate attaching two dies having different number of interconnect structures.

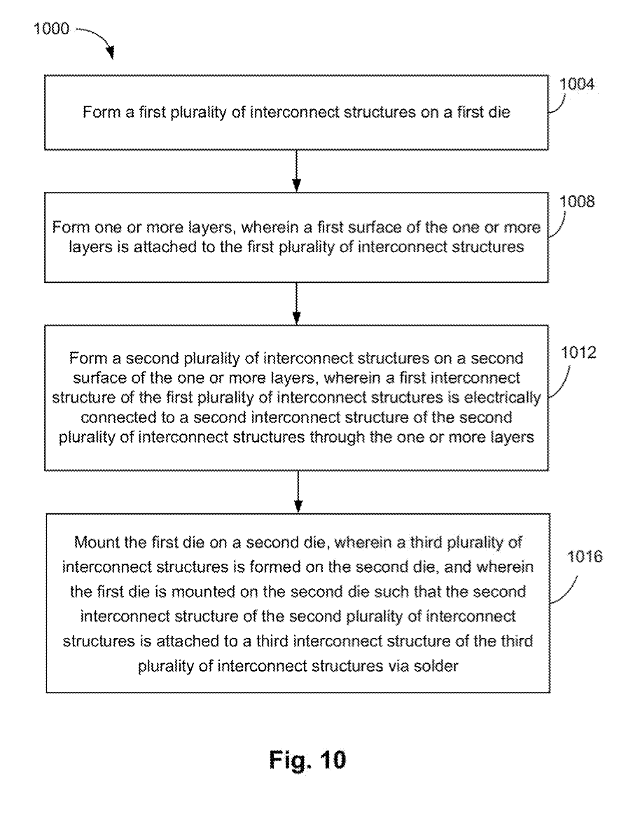

FIG. 10 illustrates a flowchart depicting a method 1000 for mounting a first die (e.g., the die 104a of FIGS. 3A-3F) on a second die (e.g., the die 102 of FIG. 3F), where a pitch of interconnect structures (e.g., interconnect structures 124) of the first die 104a is less than a pitch of interconnect structures (e.g., interconnect structures 116) of the second die 102, according to some embodiments. At 1004, a first plurality of interconnect structures (e.g., the interconnect structures 124) is formed on the first die.

At 1008, one or more layers (e.g., layers 316a, 316b, and/or 316c) are formed. In some embodiments, a first surface of the one or more layers 316 is attached to the first plurality of interconnect structures 124.

At 1012, a second plurality of interconnect structures (e.g., interconnect structures 320) is formed on a second surface of the one or more layers 316. In an example, a first interconnect structure (e.g., the interconnect structure 124a) of the first plurality of interconnect structures is electrically connected to a second interconnect structure (e.g., interconnect structure 320a) of the second plurality of interconnect structures 320 through the one or more layers.

At 1016, the first die 104a is mounted on the second die 102. In some embodiments, a third plurality of interconnect structures (e.g., interconnect structures 116) is formed on the second die 102. In an example, the first die 104a is mounted on the second die 102 such that the second interconnect structure 320a of the second plurality of interconnect structures 320 is attached to a third interconnect structure (e.g., interconnect structure 116a) of the third plurality of interconnect structures 116 via, for example, solder.

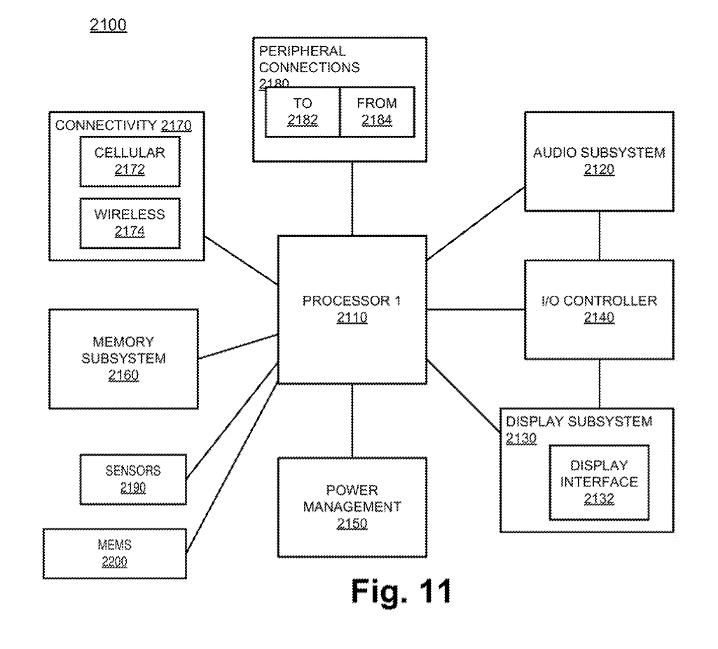

FIG. 11 illustrates a computing device 2100, a smart device, a computing device or a computer system or a SoC (System-on-Chip) 2100, in which a first die is stacked on a second die in a flip chip configuration, where the interconnect structures of the first and second dies are dissimilar, according to some embodiments. It is pointed out that those elements of FIG. 11 having the same reference numbers (or names) as the elements of any other figure can operate or function in any manner similar to that described, but are not limited to such.

Here, the various blocks forming the computing device 2100 may be packaged as a stack of dies, e.g., a first die 102 of FIG. 3F and a second die 104a of FIG. 3F (and possibly a third die 104b of FIG. 3F), where the interconnect structures of the first and second dies are dissimilar. Here, one or more blocks forming the computing device 2100 may be packaged, for example, in one or more of the packages 300f, 400, 500e, 600, 700g, 800g, and/or 900.

In some embodiments, computing device 2100 represents an appropriate computing device, such as a computing tablet, a mobile phone or smart-phone, a laptop, a desktop, an IOT device, a server, a set-top box, a wireless-enabled e-reader, or the like. It will be understood that certain components are shown generally, and not all components of such a device are shown in computing device 2100.

In some embodiments, computing device 2100 includes a first processor 2110. The various embodiments of the present disclosure may also comprise a network interface within 2170 such as a wireless interface so that a system embodiment may be incorporated into a wireless device, for example, cell phone or personal digital assistant.

In one embodiment, processor 2110 can include one or more physical devices, such as microprocessors, application processors, microcontrollers, programmable logic devices, or other processing means. The processing operations performed by processor 2110 include the execution of an operating platform or operating system on which applications and/or device functions are executed. The processing operations include operations related to I/O (input/output) with a human user or with other devices, operations related to power management, and/or operations related to connecting the computing device 2100 to another device. The processing operations may also include operations related to audio I/O and/or display I/O.

In one embodiment, computing device 2100 includes audio subsystem 2120, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 2100, or connected to the computing device 2100. In one embodiment, a user interacts with the computing device 2100 by providing audio commands that are received and processed by processor 2110.

Display subsystem 2130 represents hardware (e.g., display devices) and software (e.g., drivers) components that provide a visual and/or tactile display for a user to interact with the computing device 2100. Display subsystem 2130 includes display interface 2132, which includes the particular screen or hardware device used to provide a display to a user. In one embodiment, display interface 2132 includes logic separate from processor 2110 to perform at least some processing related to the display. In one embodiment, display subsystem 2130 includes a touch screen (or touch pad) device that provides both output and input to a user.

I/O controller 2140 represents hardware devices and software components related to interaction with a user. I/O controller 2140 is operable to manage hardware that is part of audio subsystem 2120 and/or display subsystem 2130. Additionally, I/O controller 2140 illustrates a connection point for additional devices that connect to computing device 2100 through which a user might interact with the system. For example, devices that can be attached to the computing device 2100 might include microphone devices, speaker or stereo systems, video systems or other display devices, keyboard or keypad devices, or other I/O devices for use with specific applications such as card readers or other devices.

As mentioned above, I/O controller 2140 can interact with audio subsystem 2120 and/or display subsystem 2130. For example, input through a microphone or other audio device can provide input or commands for one or more applications or functions of the computing device 2100. Additionally, audio output can be provided instead of, or in addition to display output. In another example, if display subsystem 2130 includes a touch screen, the display device also acts as an input device, which can be at least partially managed by I/O controller 2140. There can also be additional buttons or switches on the computing device 2100 to provide I/O functions managed by I/O controller 2140.

In one embodiment, I/O controller 2140 manages devices such as accelerometers, cameras, light sensors or other environmental sensors, or other hardware that can be included in the computing device 2100. The input can be part of direct user interaction, as well as providing environmental input to the system to influence its operations (such as filtering for noise, adjusting displays for brightness detection, applying a flash for a camera, or other features).

In one embodiment, computing device 2100 includes power management 2150 that manages battery power usage, charging of the battery, and features related to power saving operation. Memory subsystem 2160 includes memory devices for storing information in computing device 2100. Memory can include nonvolatile (state does not change if power to the memory device is interrupted) and/or volatile (state is indeterminate if power to the memory device is interrupted) memory devices. Memory subsystem 2160 can store application data, user data, music, photos, documents, or other data, as well as system data (whether long-term or temporary) related to the execution of the applications and functions of the computing device 2100.

Elements of embodiments are also provided as a machine-readable medium (e.g., memory 2160) for storing the computer-executable instructions (e.g., instructions to implement any other processes discussed herein). The machine-readable medium (e.g., memory 2160) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 2170 includes hardware devices (e.g., wireless and/or wired connectors and communication hardware) and software components (e.g., drivers, protocol stacks) to enable the computing device 2100 to communicate with external devices. The computing device 2100 could be separate devices, such as other computing devices, wireless access points or base stations, as well as peripherals such as headsets, printers, or other devices.

Connectivity 2170 can include multiple different types of connectivity. To generalize, the computing device 2100 is illustrated with cellular connectivity 2172 and wireless connectivity 2174. Cellular connectivity 2172 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 2174 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 2180 include hardware interfaces and connectors, as well as software components (e.g., drivers, protocol stacks) to make peripheral connections. It will be understood that the computing device 2100 could both be a peripheral device (“to” 2182) to other computing devices, as well as have peripheral devices (“from” 2184) connected to it. The computing device 2100 commonly has a “docking” connector to connect to other computing devices for purposes such as managing (e.g., downloading and/or uploading, changing, synchronizing) content on computing device 2100. Additionally, a docking connector can allow computing device 2100 to connect to certain peripherals that allow the computing device 2100 to control content output, for example, to audiovisual or other systems.

In addition to a proprietary docking connector or other proprietary connection hardware, the computing device 2100 can make peripheral connections 2180 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

In some embodiments, SOC 2100 includes sensors 2190 (e.g., temperature sensors, accelerometers, gyroscopes, etc.). In some embodiments, SOC 2100 includes one or more MEMs 2200 (Microelectromechanical systems).

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following example clauses pertain to further embodiments. Specifics in the example clauses may be used anywhere in one or more embodiments. All optional features of the apparatus described herein may also be implemented with respect to a method or process.

Clause 1. An apparatus comprising: a first die, wherein a first plurality of interconnect structures is formed on the first die; one or more layers, wherein a first surface of the one or more layers is attached to the first plurality of interconnect structures; a second plurality of interconnect structures formed on a second surface of the one or more layers; and a second die, wherein a third plurality of interconnect structures is formed on the second die, wherein a first interconnect structure of the first plurality of interconnect structures is electrically coupled to a second interconnect structure of the second plurality of interconnect structures through the one or more layers, and wherein the first die is mounted on the second die such that the second interconnect structure of the second plurality of interconnect structures is attached to a third interconnect structure of the third plurality of interconnect structures via an attachment component.

Clause 2. The apparatus of clause 1, wherein: the first plurality of interconnect structures has a first pitch; the second plurality of interconnect structures has a second pitch that substantially different from the first pitch; and the third plurality of interconnect structures has a third pitch that is substantially similar to the second pitch.

Clause 3. The apparatus of any of clauses 1-2, wherein: the first plurality of interconnect structures has a first number of interconnect structures; the second plurality of interconnect structures has a second number of interconnect structures, the second number being different from the first number; and the third plurality of interconnect structures has the second number of interconnect structures.

Clause 4. The apparatus of any of clauses 1-3, wherein: the third plurality of interconnect structures is formed on a first surface of the second die; and the apparatus further comprises a third die mounted on the first surface of the second die.

Clause 5. The apparatus of clause 4, wherein: a fourth plurality of interconnect structures is formed on the third die; a fifth plurality of interconnect structures is formed on the first surface of the second die; and the third die is mounted on the second die such that a fourth interconnect structure of the fourth plurality of interconnect structures is attached to a fifth interconnect structure of the fifth plurality of interconnect structures via another attachment component.

Clause 6. The apparatus of any of clauses 1-5, wherein: the one or more layers comprises one or more of a trace, a redistribution layer, and a through mold via (TMV) configured to electrically couple the first interconnect structure of the first plurality of interconnect structures to the second interconnect structure of the second plurality of interconnect structures.

Clause 7. The apparatus of any of clauses 1-6, further comprising: a substrate, wherein the second die is mounted on the substrate.

Clause 8. The apparatus of clause 7, further comprising: a through-silicon via (TSV) formed through the second die, wherein the first die is electrically coupled to the substrate through the first interconnect structure, the one or more layers, the second interconnect structure, the third interconnect structure, and the TSV formed through the second die.

Clause 9. The apparatus of any of clauses 1-7, wherein: the first die is to be wire-bonded, the first die comprising a plurality of wire-bonding pads; and the second plurality of interconnect structures are arranged in a ball grid array (BGA).

Clause 10. The apparatus of any of clauses 1-9, wherein: the first interconnect structure comprises a first metal; and the third interconnect structure comprises a second metal, such that the first interconnect structure is not attachable to the third interconnect structure via a solder due to an incompatibility of the first metal and the second metal.

Clause 11. The apparatus of any of clauses 1-10, wherein: the attachment component is a first attachment component comprising a first type of solder; and the first surface of the one or more layers is attached to the first plurality of interconnect structures with a second type of solder, the second type of solder being different from the first type of solder.

Clause 12. A semiconductor package comprising: a first die, wherein a plurality of interconnect pads is formed on a first surface of the first die; one or more layers; a first plurality of interconnect structures coupled to the first surface of the first die via the one or more layers, and wherein each interconnect structure of the first plurality of interconnect structures is electrically coupled to a corresponding interconnect pad of the plurality of interconnect pads via the one or more layers; and a second die, wherein a second plurality of interconnect structures is formed on the second die, wherein the first die is mounted on the second die such that a first interconnect structure of the first plurality of interconnect structures is coupled to a second interconnect structure of the second plurality of interconnect structures via a solder.

Clause 13. The semiconductor package of clause 12, wherein: the plurality of interconnect pads has a first pitch; and the first plurality of interconnect structures has a second pitch that is substantially different from the first pitch.

Clause 14. The semiconductor package of any of clauses 12-13, wherein: the plurality of interconnect pads comprises a plurality of bond pads arranged along a periphery of the die; and the first plurality of interconnect structures comprises a plurality of bumps arranged in a ball grid array.

Clause 15. The semiconductor package of any of clauses 12-14, wherein: the plurality of interconnect pads has a first layout; the first plurality of interconnect structures has a second layout that is substantially different from the first layout; and the second plurality of interconnect structures has a third layout that is substantially similar to the second layout.

Clause 16. The semiconductor package of any of clause 12-13, further comprising: a third die, wherein a third plurality of interconnect structures is formed on the third die, wherein the second plurality of interconnect structures is formed on a first surface of the second die, wherein a fourth plurality of interconnect structures is formed on the first surface of the second die, and wherein the third die is mounted on the first surface of the second die in a flip-chip configuration such that a third interconnect structure of the third plurality of interconnect structures is coupled to a fourth interconnect structure of the fourth plurality of interconnect structures.

Clause 17. The semiconductor package of any of clauses 12-16, further comprising: a substrate, wherein the second die is mounted on the substrate in a flip-chip configuration.

Clause 18. The semiconductor package of clause 17, further comprising: a through-silicon-via (TSV) formed through at least a section of the second die, wherein the first die is electrically coupled to the substrate through a first wire bonding pad of the plurality of wire bonding pads, the one or more layers, the first interconnect structure, the second interconnect structure, and the TSV.

Clause 19. The semiconductor package of any of clauses 12-18, wherein the one or more layers comprises: a first metal connection coupled to the first surface of the first die, wherein the first metal connection is electrically coupled to a first interconnect pad of the plurality of interconnect pads; a dielectric layer, wherein the first plurality of interconnect structures is coupled to the dielectric layer; and a first through-mold-via (TMV) formed through the dielectric layer, wherein the first interconnect structure of the first plurality of interconnect structures is electrically coupled to the first metal connection through the first TMV.

Clause 20. A method comprising: forming a first plurality of interconnect structures on a first die; forming one or more layers, wherein a first surface of the one or more layers is coupled to the first plurality of interconnect structures; forming a second plurality of interconnect structures on a second surface of the one or more layers, wherein a first interconnect structure of the first plurality of interconnect structures is electrically coupled to a second interconnect structure of the second plurality of interconnect structures through the one or more layers; and mounting the first die on a second die, wherein a third plurality of interconnect structures is formed on the second die, and wherein the first die is mounted on the second die such that the second interconnect structure of the second plurality of interconnect structures is coupled to a third interconnect structure of the third plurality of interconnect structures via solder.

Clause 21. The method of clause 20, wherein: the first plurality of interconnect structures has a first pitch; the second plurality of interconnect structures has a second pitch that is substantially different from the first pitch; and the third plurality of interconnect structures has a third pitch that is substantially similar to the second pitch.

Clause 22. The method of any of clauses 20-21, wherein the third plurality of interconnect structures is formed on a first surface of the second die, and the method further comprises: mounting a third die on the first surface of the second die.

Clause 23. The method of any of clauses 20-22, further comprising: mounting the second die on a substrate.

Clause 24. The method of any of clauses 20-23, wherein: the first plurality of interconnect structures has a first number of interconnect structures; the second plurality of interconnect structures has a second number of interconnect structures, the second number being different from the first number; and the third plurality of interconnect structures has the second number of interconnect structures.

Clause 25. An apparatus comprising means for performing the method of any of clauses 20-24.

Clause 26. An apparatus comprising: means for forming a first plurality of interconnect structures on a first die; means for forming one or more layers, wherein a first surface of the one or more layers is coupled to the first plurality of interconnect structures; means for forming a second plurality of interconnect structures on a second surface of the one or more layers, wherein a first interconnect structure of the first plurality of interconnect structures is electrically coupled to a second interconnect structure of the second plurality of interconnect structures through the one or more layers; and means for mounting the first die on a second die, wherein a third plurality of interconnect structures is formed on the second die, and wherein the first die is mounted on the second die such that the second interconnect structure of the second plurality of interconnect structures is coupled to a third interconnect structure of the third plurality of interconnect structures via solder.

Clause 27. The apparatus of clause 26, wherein: the first plurality of interconnect structures has a first pitch; the second plurality of interconnect structures has a second pitch that is substantially different from the first pitch; and the third plurality of interconnect structures has a third pitch that is substantially similar to the second pitch.

Clause 28. The apparatus of any of clauses 26-27, wherein the third plurality of interconnect structures is formed on a first surface of the second die, and the apparatus further comprises: means for mounting a third die on the first surface of the second die.

Clause 29. The apparatus of any of clauses 26-28, further comprising: means for mounting the second die on a substrate.

Clause 30. The apparatus of any of clauses 26-29, wherein: the first plurality of interconnect structures has a first number of interconnect structures; the second plurality of interconnect structures has a second number of interconnect structures, the second number being different from the first number; and the third plurality of interconnect structures has the second number of interconnect structures.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1-25. (canceled)

26. An apparatus comprising:
a first die, wherein a first plurality of interconnect structures is on the first die;
one or more layers, wherein a first surface of the one or more layers is adjacent to the first plurality of interconnect structures;
a second plurality of interconnect structures on a second surface of the one or more layers; and
a second die, wherein a third plurality of interconnect structures is on the second die,
wherein a first interconnect structure of the first plurality of interconnect structures is electrically coupled to a second interconnect structure of the second plurality of interconnect structures through the one or more layers, and
wherein the first die is on the second die such that the second interconnect structure of the second plurality of interconnect structures is adjacent to a third interconnect structure of the third plurality of interconnect structures via an attachment component.

27. The apparatus of claim 26, wherein:
the first plurality of interconnect structures has a first pitch;
the second plurality of interconnect structures has a second pitch that is substantially different from the first pitch; and
the third plurality of interconnect structures has a third pitch that is substantially similar to the second pitch.

28. The apparatus of claim 26, wherein:
the first plurality of interconnect structures has a first number of interconnect structures;
the second plurality of interconnect structures has a second number of interconnect structures, the second number being different from the first number; and
the third plurality of interconnect structures has the second number of interconnect structures.

29. The apparatus of claim 26, wherein:
the third plurality of interconnect structures is on a first surface of the second die; and
the apparatus further comprises a third die on the first surface of the second die.

30. The apparatus of claim 29, wherein:
a fourth plurality of interconnect structures is on the third die;
a fifth plurality of interconnect structures is on the first surface of the second die; and
the third die is mounted on the second die such that a fourth interconnect structure of the fourth plurality of interconnect structures is adjacent to a fifth interconnect structure of the fifth plurality of interconnect structures via another attachment component.

31. The apparatus of claim 26, wherein:
the one or more layers comprises one or more of a trace, a redistribution layer, and a through mold via (TMV) to electrically couple the first interconnect structure of the first plurality of interconnect structures to the second interconnect structure of the second plurality of interconnect structures.

32. The apparatus of claim 26, further comprising:
a substrate, wherein the second die is on the substrate.

33. The apparatus of claim 32, further comprising:
a through-silicon via (TSV) through the second die, wherein the first die is electrically coupled to:
the substrate through the first interconnect structure,
the one or more layers,
the second interconnect structure,
the third interconnect structure, and
the TSV formed through the second die.

34. The apparatus of claim 26, wherein:
the first die is to be wire-bonded, the first die comprising a plurality of wire-bonding pads; and
the second plurality of interconnect structures are arranged in a ball grid array (BGA).

35. The apparatus of claim 26, wherein:
the first interconnect structure comprises a first metal; and
the third interconnect structure comprises a second metal, such that the first interconnect structure is not attachable to the third interconnect structure via a solder due to an incompatibility of the first metal and the second metal.

36. The apparatus of claim 26, wherein:
the attachment component is a first attachment component comprising a first type of solder; and
the first surface of the one or more layers is attached to the first plurality of interconnect structures with a second type of solder, the second type of solder being different from the first type of solder.

37. A semiconductor package comprising:
a first die, wherein a plurality of interconnect pads is on a first surface of the first die;
one or more layers;
a first plurality of interconnect structures coupled to the first surface of the first die via the one or more layers, and wherein each interconnect structure of the first plurality of interconnect structures is electrically coupled to a corresponding interconnect pad of the plurality of interconnect pads via the one or more layers; and
a second die, wherein a second plurality of interconnect structures is on the second die,
wherein the first die is mounted on the second die such that a first interconnect structure of the first plurality of interconnect structures is coupled to a second interconnect structure of the second plurality of interconnect structures via a solder.

38. The semiconductor package of claim 37, wherein:
the plurality of interconnect pads has a first pitch; and
the first plurality of interconnect structures has a second pitch that is substantially different from the first pitch.

39. The semiconductor package of claim 37, wherein:
the plurality of interconnect pads comprises a plurality of bond pads arranged along a periphery of the die; and
the first plurality of interconnect structures comprises a plurality of bumps arranged in a ball grid array.

40. The semiconductor package of claim 37, wherein:
the plurality of interconnect pads has a first layout;
the first plurality of interconnect structures has a second layout that is substantially different from the first layout; and
the second plurality of interconnect structures has a third layout that is substantially similar to the second layout.

41. The semiconductor package of claim 37, further comprising:
a third die,
wherein a third plurality of interconnect structures is on the third die,
wherein the second plurality of interconnect structures is on a first surface of the second die,
wherein a fourth plurality of interconnect structures is on the first surface of the second die, and
wherein the third die is mounted on the first surface of the second die in a flip-chip configuration such that a third interconnect structure of the third plurality of interconnect structures is coupled to a fourth interconnect structure of the fourth plurality of interconnect structures.

42. The semiconductor package of claim 37, further comprising:
a substrate, wherein the second die is on the substrate in a flip-chip configuration.

43. The semiconductor package of claim 42, further comprising:
a through-silicon-via (TSV) through at least a section of the second die,
wherein the first die is electrically coupled to:
the substrate through a first wire bonding pad of the plurality of wire bonding pads,
the one or more layers,
the first interconnect structure,
the second interconnect structure, and
the TSV.

44. The semiconductor package of claim 37, wherein the one or more layers comprises:
a first metal connection coupled to the first surface of the first die, wherein the first metal connection is electrically coupled to a first interconnect pad of the plurality of interconnect pads;
a dielectric layer, wherein the first plurality of interconnect structures is coupled to the dielectric layer; and
a first through-mold-via (TMV) through the dielectric layer, wherein the the first interconnect structure of the first plurality of interconnect structures is electrically coupled to the first metal connection through the first TMV.

45. A method comprising:
forming a first plurality of interconnect structures on a first die;
forming one or more layers, wherein a first surface of the one or more layers is coupled to the first plurality of interconnect structures;
forming a second plurality of interconnect structures on a second surface of the one or more layers, wherein a first interconnect structure of the first plurality of interconnect structures is electrically coupled to a second interconnect structure of the second plurality of interconnect structures through the one or more layers; and
mounting the first die on a second die, wherein a third plurality of interconnect structures is formed on the second die, and wherein the first die is mounted on the second die such that the second interconnect structure of the second plurality of interconnect structures is coupled to a third interconnect structure of the third plurality of interconnect structures via solder.

46. The method of claim 45, wherein:
the first plurality of interconnect structures has a first pitch;
the second plurality of interconnect structures has a second pitch that is substantially different from the first pitch; and
the third plurality of interconnect structures has a third pitch that is substantially similar to the second pitch.

47. The method of claim 45, wherein the third plurality of interconnect structures is formed on a first surface of the second die, and the method further comprises:
mounting a third die on the first surface of the second die.

48. The method of claim 45, further comprising:
mounting the second die on a substrate.
